(19) United States
(12) Patent Application Publication
(10) Pub. No.: US 2012/0139027 A1
(43) Pub. Date: Jun. 7, 2012

(54) VERTICAL STRUCTURE NON-VOLATILE MEMORY DEVICES INCLUDING IMPURITY PROVIDING LAYER

(75) Inventors: Byoung-keun Son, Suwon-si (KR); Chang-hyun Lee, Suwon-si (KR)

(73) Assignee: Samsung Electronics Co., Ltd.

(21) Appl. No.: 13/238,368

(22) Filed: Sep. 21, 2011

(30) Foreign Application Priority Data
Dec. 2, 2010 (KR) 10-2010-0122005

(51) Int. Cl. H01L 29/78; H01L 29/772

(52) U.S. Cl. 257/324; 257/314; 257/E29.262; 257/E29.309

(57) ABSTRACT

A vertical structure non-volatile memory device includes a channel region that vertically extends on a substrate. A memory cell string vertically extends on the substrate along a first wall of the channel regions, and includes at least one selection transistor and at least one memory cell. An impurity providing layer is disposed on a second wall of the channel region and includes impurities.

### CROSS-REFERENCE TO RELATED APPLICATION

This application claims the benefit of Korean Patent Application No. 10-2010-0122005, filed on Dec. 2, 2010, in the Korean Intellectual Property Office, the disclosure of which is incorporated herein in its entirety by reference.

### BACKGROUND

Various embodiments described herein relate to transistor structures including vertical transistor structures, such as vertical transistor structure non-volatile memory devices, and related fabrication methods.

Recently, electronic products have been required to have small volumes and process a large amount of data. Thus, there is a desire to increase integration of semiconductor memory devices used in electronic products. As one method of increasing integration of semiconductor memory devices, a non-volatile memory device having a vertical transistor structure instead of a typical flat transistor has been suggested. For example, vertical structure NAND flash memory devices have been provided.

### SUMMARY

Various embodiments described herein can provide a vertical structure non-volatile memory device that can control current characteristics of a memory cell string and can provide improved reliability, and methods of fabricating same.

Various embodiments described herein can provide a semiconductor device such as a vertical transistor structure that can control current characteristics and that can provide improved reliability, and methods of fabricating same.

Various embodiments described herein can provide a system including a non-volatile memory device including a vertical structure non-volatile memory device, and methods of fabricating same.

According to various embodiments described herein, there is provided a vertical structure non-volatile memory device including a channel region that vertically extends on a substrate and a memory cell string that vertically extends on the substrate along a first wall of the channel region, and includes at least one selection transistor and at least one memory cell transistor. An impurity providing layer is disposed on a second wall of the channel region and including impurities therein.

The impurity providing layer may include an insulating material doped with impurities and/or a semiconductor material doped with impurities. For example, the impurity providing layer may include any one or more of phosphosilicate glass (PSG), borosilicate glass (BSG), or doped polysilicon. The impurity providing layer may include a semiconductor material doped with impurities, and the channel region may be electrically connected to the substrate through the impurity providing layer. The channel region may have a first impurity concentration, and the impurity providing layer may have a second impurity concentration that is higher than the first impurity concentration. The first impurity concentration may be from 10¹⁸/cm³ to 10¹⁹/cm³, and the second impurity concentration may be from 10¹⁹/cm³ to 10²¹/cm³. The channel region may be electrically connected to the substrate. The impurities may be group III or V elements that may be diffused from the impurity providing layer to the channel region by heat-treatment.

The vertical structure non-volatile memory device may further include a diffusion controlling layer disposed between the channel region and the impurity providing layer. The diffusion controlling layer may be configured to reduce, but not block, diffusion of impurities from the impurity providing layer to the channel region. The channel region may be electrically connected to the substrate through the diffusion controlling layer.

The vertical structure non-volatile memory device may further include a bit line connected to one side of the memory cell string, and a common source line connected to the other end of the memory cell string at an opposite side of the bit line. The common source line may vertically extend on the substrate between memory cell strings that are adjacent to each other. A pair of the selection transistors that are connected in series may be arranged between the bit line and the memory cells. The at least one memory cell and the at least one selection transistor may include a gate dielectric layer and a gate electrode on the first wall of the channel region. The gate dielectric layer may include a tunneling insulating layer, an electric charge storage layer, and a blocking insulating layer, which are sequentially stacked from the channel region.

According to other embodiments described herein, there is provided a semiconductor device comprising a transistor including a channel region, and an impurity providing layer disposed at one side of the channel region, and including impurities to be provided to the channel region. The impurity providing layer may include an insulating material doped with impurities and/or a semiconductor material doped with impurities. The channel region may have a first impurity concentration, and the impurity providing layer may have a second impurity concentration that is higher than the first impurity concentration.

According to various embodiments described herein, there is provided a system including a memory including a vertical structure non-volatile memory device according to various embodiments described herein, a processor communicating with the memory through a bus, and an input/output device communicating via the bus.

Vertical transistor structures according to various other embodiments described herein comprise a substrate including a horizontal surface and a column on the substrate that extends vertically away from the horizontal surface that includes a wall that extends vertically away from the horizontal surface. A channel region is on the wall of the column and extends vertically away from the horizontal surface. A gate dielectric is on the channel region opposite the column and extends vertically away from the horizontal surface. A plurality of gate electrodes are stacked upon one another on the horizontal surface and extend adjacent the gate dielectric opposite the channel region. The column is more heavily doped with impurities than the channel region.

The gate dielectric may comprise a tunneling insulator, a charge storage layer and a blocking insulating layer, all of which extend vertically away from the horizontal surface. The column may comprise a hollow or solid column that is doped with the impurities. The column may also comprise semiconductor material and/or insulating material that is doped with the impurities. A diffusion controlling layer also may be provided between the channel region and the column. The diffusion controlling layer extends vertically away from the horizontal surface and is configured to reduce, but not block, diffusion of the impurities from the column to the channel region.

### BRIEF DESCRIPTION OF THE DRAWINGS

Various embodiments described herein will be more clearly understood from the following detailed description taken in conjunction with the accompanying drawings in which:

FIG. 1 is an equivalent circuit diagram of a memory cell array of a non-volatile memory device according to various embodiments described herein;

FIG. 2 is an equivalent circuit diagram of a memory cell string of a non-volatile memory device according to various embodiments described herein;

FIG. 3 is a schematic perspective view of a three-dimensional (3D) structure of memory cells strings of a non-volatile memory device according to various embodiments described herein;

FIGS. 4A through 4H are cross-sectional views for describing methods of manufacturing a non-volatile memory device of FIG. 3, according to various embodiments described herein;

FIG. 5 is a schematic perspective view of a 3D structure of memory cells strings of a non-volatile memory device according to various embodiments described herein;

FIG. 6 is a schematic perspective view of a 3D structure of memory cells strings of a non-volatile memory device according to various embodiments described herein;

FIG. 7 is a schematic perspective view of a 3D structure of memory cells strings of a non-volatile memory device according to various embodiments described herein;

FIGS. 8A through 8F are cross-sectional views for describing methods of manufacturing a non-volatile memory device of FIG. 7 according to various embodiments described herein;

FIG. 9 is a schematic perspective view of a 3D structure of memory cells strings of a non-volatile memory device according to various embodiments described herein;

FIG. 10 is a schematic perspective view of a 3D structure of memory cells strings of a non-volatile memory device according to various embodiments described herein;

FIGS. 11A and 11B are graphs showing simulation results of hot temperature stress (HTS) characteristics of a non-volatile memory device according to various embodiments described herein;

FIG. 12 is a schematic block diagram of a non-volatile memory device according to various embodiments described herein;

FIG. 13 is a schematic diagram of a memory card according to various embodiments described herein; and

FIG. 14 is a schematic diagram of an electronic system according to various embodiments described herein.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Relative terms may be used herein to describe one element's relationship to another element as illustrated in the Figures. These relative terms generally relate to an element's position relative to a substrate, when the substrate is at the bottom of a drawing. However, it will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, can therefore, encompasses both an orientation of “lower” and “upper,” depending on the particular orientation of the figure. Similarly, if the structure in one of the figures is turned over, elements described as “below”, “beneath” or “under” other elements would then be oriented “above” or “over” the other elements. The exemplary terms “below”, “beneath”, “under” “above” and “over” can, therefore, encompass both an orientation of above and below. Also, the terms “horizontal” and “vertical,” and the terms “x”, “y” and “z” are used herein to describe generally orthogonal directions and do not imply a specific orientation.

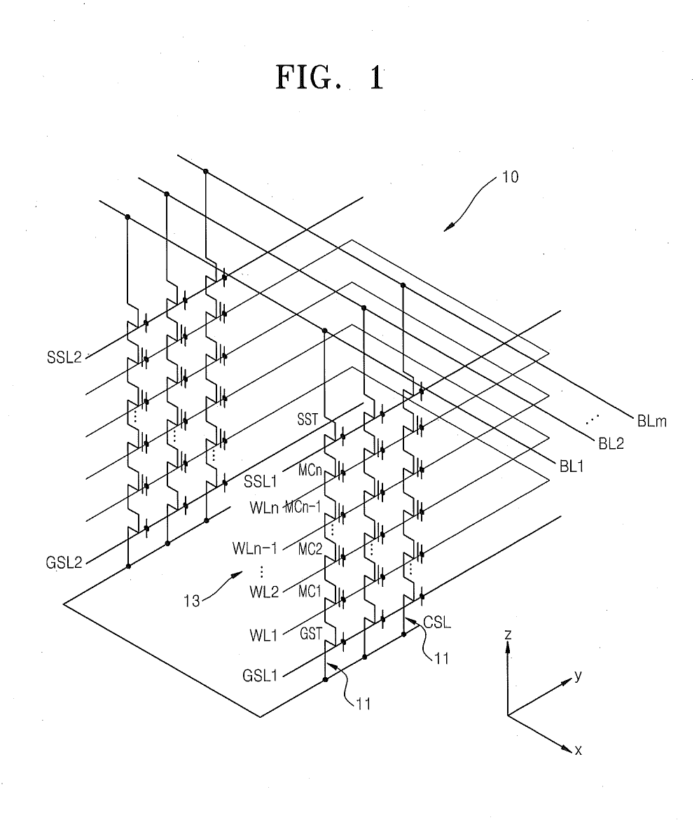

FIG. 1 is an equivalent circuit diagram of a memory cell array 10 of a non-volatile memory device according to various embodiments described herein. FIG. 1 shows an equivalent circuit diagram of a vertical structure NAND flash memory device having a vertical channel structure.

Referring to FIG. 1, the memory cell array 10 may include a plurality of memory cell strings 11. Each of the memory cell strings 11 may include a vertical structure that extends in a vertical direction (that is, a z-axis direction) orthogonal to directions (that is, x-axis and y-axis directions) in which a main surface of a substrate (not shown) extends. The memory cell strings 11 may constitute a memory cell block 13.

Each of the memory cell strings 11 may include a plurality of memory cells MC1 to MCn, a string selection transistor SST, and a ground selection transistor GST, where n is any positive integer). In each of the memory cell strings 11, the ground selection transistor GST, the memory cells MC1 to MCn, and the string selection transistor SST may be arranged in series in the vertical direction (that is, a z-axis direction). In this case, the memory cells MC1 to MCn may store data. A plurality of word lines WL1 to WLn may be connected to the memory cells MC1 to MCn so as control the memory cells MC1 to MCn, respectively. The number of memory cells MC1 to MCn may be appropriately selected according to capacity of a semiconductor memory device.

A plurality of bit lines BL1 to BLm extending in the x-axis direction are connected to first ends of the memory cell strings 11 arranged in 1^{st} to m^{th} columns of the memory cell block 13, for example, to drain terminals of string selection transistors SST. In addition, a common source line CSL is connected to second ends of the memory cell strings 11, for example, sources of ground selection transistors GST.

The word lines WL1 to WLn that extend in the y-axis direction may be commonly connected to gates of the memory cells MC1 to MCn, which are disposed on the same plane, from among the memory cells MC1 to MCn of the memory cell strings 11. According to driving of the word lines WL1 to WLn, data may be programmed, read, or removed in the memory cells MC1 to MCn.

In each of the memory cell strings 11, the string selection transistors SST may be disposed between the bit lines BL1 to BLm and the memory cells MC1 to MCn. In the memory cell block 13, each string selection transistor SST may control data transmission between the bit lines BL1 to BLm and the memory cells MC1 to MCn by a string selection line SSL connected to a gate of the string selection transistor SST.

In each of the memory cell strings, the ground selection transistors GST may be disposed between the memory cells MC1 to MCn and the common source line CSL. In the memory cell block 13, each ground selection transistor GST may control data transmission between the memory cells MC1 to MCn and the common source line CSL by a ground selection line GSL connected to a gate of the ground selection transistor GST.

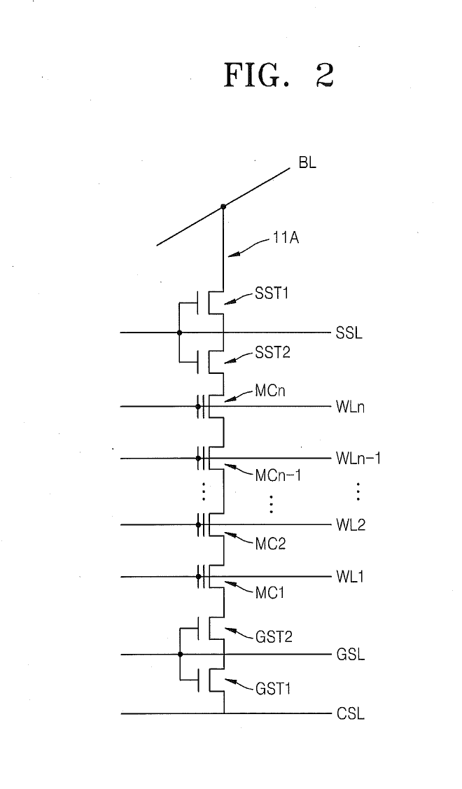

FIG. 2 is an equivalent circuit diagram of a memory cell string 11A of a non-volatile memory device according to various embodiments described herein. FIG. 2 shows a single equivalent circuit diagram included in a vertical structure NAND flash memory device having a vertical channel structure.

In FIGS. 1 and 2, like reference numerals refer to like elements and, thus, the detailed description thereof will be omitted.

FIG. 1 shows a case where the string selection transistor SST includes a single transistor. However, in FIG. 2, the string selection transistor SST of FIG. 1 is replaced with string selection transistors SST1 and SST2 as a pair of transistors that are arranged in series between a bit line BL and the memory cells MC1 to MCn. In this case, the string selection line SSL may be commonly connected to a gate of each of the string selection transistors SST1 and SST2. In this case, the string selection line SSL may correspond to a first string selection line SSL1 or a second string selection line SSL2 of FIG. 1.

In addition, FIG. 1 shows a case where the ground selection transistor GST includes a single transistor. However, in FIG. 2, the ground selection transistor GST of FIG. 1 is replaced with ground selection transistors GST1 and GST2 as a pair of transistors that are arranged in series between the memory cells MC1 to MCn and the common source line CSL. In this case, the ground selection line GSL may be commonly connected to a gate of each of the ground selection transistors GST1 and GST2. The ground selection line GSL may correspond to a first ground selection line GSL1 or a second ground selection line GSL2 of FIG. 1.

The bit line BL may correspond to any one of the bit lines BL1 to BLm of FIG. 1.

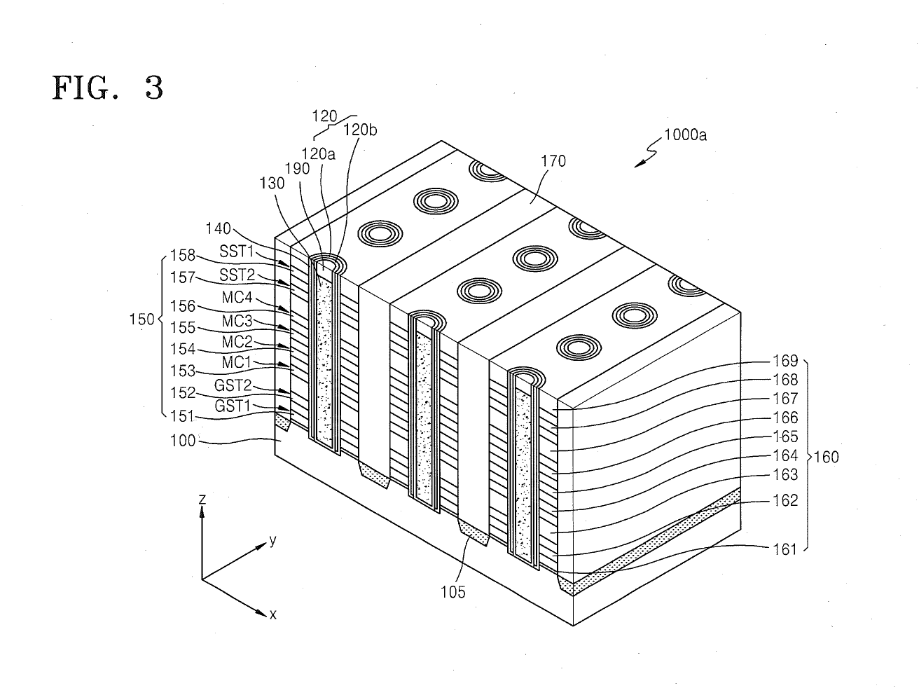

FIG. 3 is a schematic perspective view of a three-dimensional (3D) structure of memory cells strings of a non-volatile memory device 1000a according to various embodiments described herein.

In FIG. 3, some components of the memory cell strings 11 of FIG. 1 are omitted. For example, bit lines of the memory cell strings 11 of FIG. 1 are omitted.

Referring to FIG. 3, the non-volatile memory device 1000a includes a plurality of channel regions 120 disposed on a substrate 100, and a plurality of memory cell strings that are respectively arranged along walls of the channel regions 120. The memory cell strings may be arranged in the y-axis direction along the lateral walls of the channel regions 120, which are disposed in the y-axis direction. As illustrated in FIG. 3, the memory cell strings 11 or 11A (see FIGS. 1 and 2) extending in the z-axis direction may be arranged from the substrate 100 along the lateral walls of the channel regions 120. Each of the memory cell strings 11 or 11A may include two ground selection transistors GST1 and GST2, a plurality of memory cells MC1, MC2, MC3 and MC4, and two string selection transistors SST1 and SST2.

The substrate 100 may have a main horizontal surface that extends in the x-axis and y-axis directions. The substrate 100 may include a semiconductor material, for example, a group IV semiconductor, a group III to V compound semiconductor and/or a group II to VI oxide semiconductor. For example, examples of the group IV semiconductor may include silicon (Si), germanium (Ge), or Si—Ge. The substrate 100 may be a bulk wafer or an epitaxial layer.

Each channel region 120 having a column shape may be disposed on the substrate 100 so as to extend in the z-axis direction. The channel regions 120 each include a first channel layer 120a and a second channel layer 120b. The channel regions 120 may be spaced apart from each other in the x-axis and y-axis directions. The channel region 120 may be formed, for example, in an annular shape. A bottom surface of the second channel layer 120b directly contacts the substrate 100 so as to be electrically connected thereto. The channel region 120 may include a semiconductor material such as polysilicon or single crystalline silicon, and the semiconductor material may include p-type or n-type impurities.

An impurity providing layer 130 may be disposed in the channel region 120. The impurity providing layer 130 may be formed of an insulating material including impurities such as a group III element and/or a group V element in order to provide impurities to the channel region 120. The impurities may include, for example, n-type impurities such as phosphorus (P), arsenic (As) and/or antimony (Sb), or p-type impurities such as boron (B), aluminum (Al), gallium (Ga) and/or zinc (Zn). For example, the impurity providing layer 130 may include phosphosilicate glass (PSG) and/or borosilicate glass (BSG). The impurity providing layer 130 may have a higher impurity concentration than that of the channel region 120, and the impurities thereof may diffuse into the channel region 120 by heat applied during the manufacture of the non-volatile memory device 1000a.

A conductive layer 190 covers an upper surface of the impurity providing layer 130, and is electrically connected to the channel region 120. The conductive layer 190 may include doped polysilicon. The conductive layer 190 may function as a drain region of the string selection transistors SST1 and SST2.

The first string selection transistors SST1 arranged in the x-axis direction may be commonly connected to the bit lines BL (see FIG. 1) through conductive layers 190. The bit lines (not shown) may each have a pattern having a line shape extending in the x-axis direction, and may be electrically connected to the conductive layer 190 through a contact electrode (not shown) formed on the conductive layer 190. In addition, the first ground selection transistors GST1 extending in the x-axis direction are electrically connected to impurity regions 105 adjacent thereto.

The impurity regions 105 may be adjacent to the main surface of the substrate 100, extend in the y-axis direction, and may be spaced apart from each other in the x-axis direction. The impurity regions 105 and the channel regions 120 may be alternately arranged in the x-axis direction. The impurity regions 105 may be source regions, and may form a PN junction with another region of the substrate 100. The common source line CSL of FIGS. 1 and 2 may be connected to the impurity regions 105 on a region that is not shown. The impurity regions 105 may include high-concentration impurity regions (not shown) that are adjacent to the main surface of the substrate 100 and are disposed on a central portion of the substrate 100, and low-concentration impurity regions (not shown) that are disposed at two ends of each high-concentration impurity region. Insulating regions 170 may be respectively formed on the impurity regions 105.

Each insulating region 170 may be formed between the channel regions 120. That is, the insulating region 170 may be formed between adjacent memory cell strings using different channel regions 120.

A plurality of gate electrodes 151 to 158 (collectively 150) may be spaced apart from each other in the z-axis direction from the substrate 100 along the lateral walls of the channel regions 120. The gate electrodes 150 may be gate electrodes of the ground selection transistors GST1 and GST2, the memory cells MC1, MC2, MC3 and MC4, and the string selection transistors SST1 and SST2, respectively. The gate electrodes 150 may be commonly connected to memory cell strings that are adjacent in the y-axis direction. The gate electrodes 157 and 158 of the string selection transistors SST1 and SST2 may be connected to the string selection line SSL (see FIG. 1). The gate electrodes 153, 154, 155 and 156 of the memory cells MC1, MC2, MC3 and MC4 may be connected to the word lines WL1, WL2, WLn-1 and WLn (see FIGS. 1 and 2). The gate electrodes 151 and 152 of the ground selection transistors GST1 and GST2 may be connected to the ground selection line GSL (see FIG. 1). The gate electrodes 150 may include a metal layer, for example, a tungsten (W) layer. Although not illustrated, the gate electrodes 150 may further include a diffusion barrier (not shown). The diffusion barrier may include any one of tungsten nitride (WN), tantalum nitride (TaN) and titanium nitride (TiN).

A gate dielectric layer 140 may be disposed between the channel region 120 and the gate electrodes 150. Although not illustrated in detail in FIG. 3, the gate dielectric layer 140 may include a tunneling insulating layer, a charge storage layer, and a blocking insulating layer, which are sequentially stacked from the channel region 120.

The tunneling insulating layer may tunnel electric charges to the charge storage layer by using a Fowler-Nordheim (F-N) method. The tunneling insulating layer may include, for example, silicon oxide. The charge storage layer may be a charge trap layer or a floating gate conductive layer. For example, the charge storage layer may include quantum dots or nanocrystals. In this case, the quantum dots or nanocrystals may include an electric conductor, for example, minute particles of metal or semiconductor. The blocking insulating layer may include a high-k dielectric material. In this case, the high-k dielectric material refers to a dielectric material having a higher dielectric constant than that of an oxide layer.

A plurality of interlayer insulating layers 161 to 169 (collectively 160) may be disposed between the gate electrodes 150. The interlayer insulating layers 160 may be spaced apart from each other in the z-axis direction, and may extend in the y-axis direction, like the gate electrodes 150. One side of each interlayer insulating layer 160 may contact the gate dielectric layer 140. The interlayer insulating layers 160 may include silicon oxide and/or silicon nitride.

In FIG. 3, four memory cells MC1, MC2, MC3 and MC4 are illustrated, but the number of memory cells is just an example. That is, according to capacity of the non-volatile memory device 1000a, the number of memory cells MC1, MC2, MC3 and MC4 may differ. In addition, a pair of the string selection transistors SST1 and SST2 and a pair of the ground selection transistors GST1 and GST2 of memory cell strings are illustrated. However, various embodiments described herein are not limited thereto. That is, like the string selection transistor SST and the ground selection transistor GST of the memory cell string of FIG. 1, a single string selection transistor SST and a single ground selection transistor GST may be arranged. In addition, the string selection transistor SST and the ground selection transistor GST may be different from the memory cells MC1, MC2, MC3 and MC4.

In the non-volatile memory device 1000a having a 3D vertical structure according to various embodiments described herein, while it is difficult to uniformly dope the channel region 120 with impurities by ion-implantation due to a high aspect ratio of the channel region 120, impurities may be uniformly provided to the channel region 120 by the impurity providing layer 130. Thus, threshold voltages of a memory cell and a selection transistor can be controlled, and the characteristics of a memory cell string, such as cell string current characteristics, can be controlled.

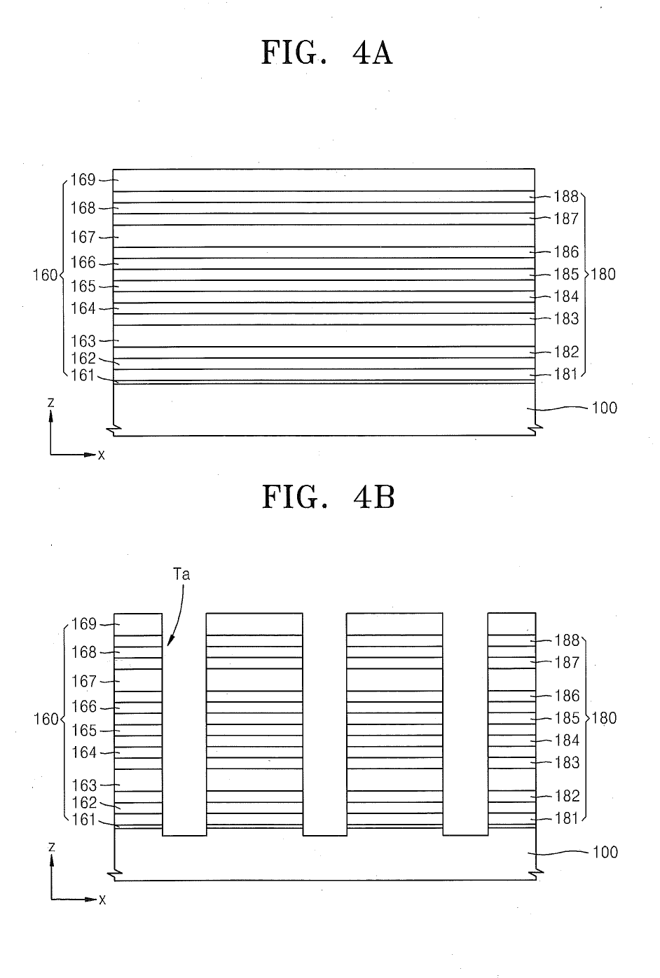

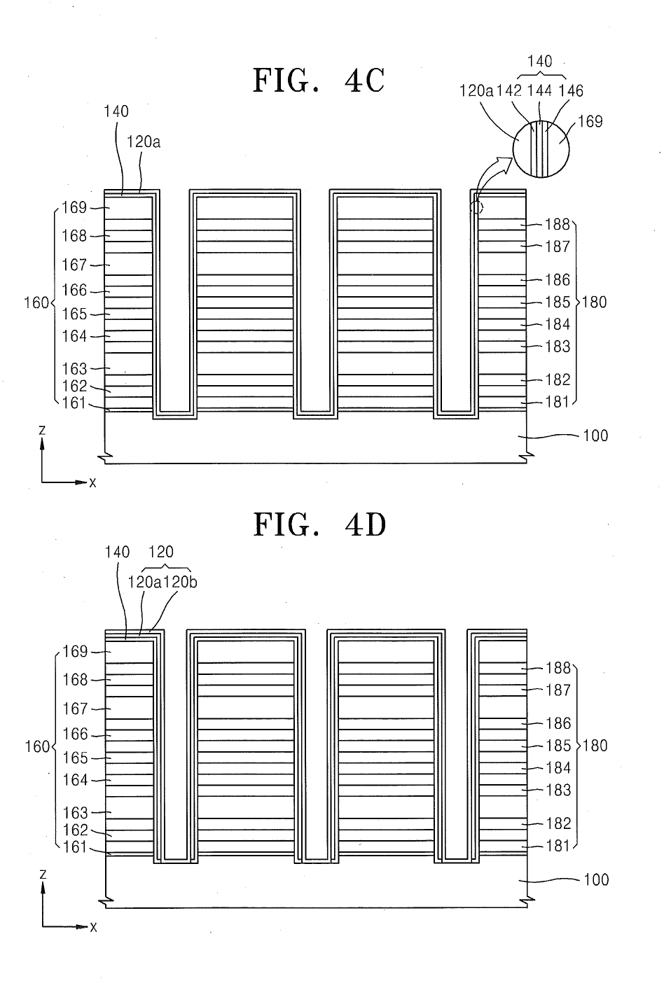

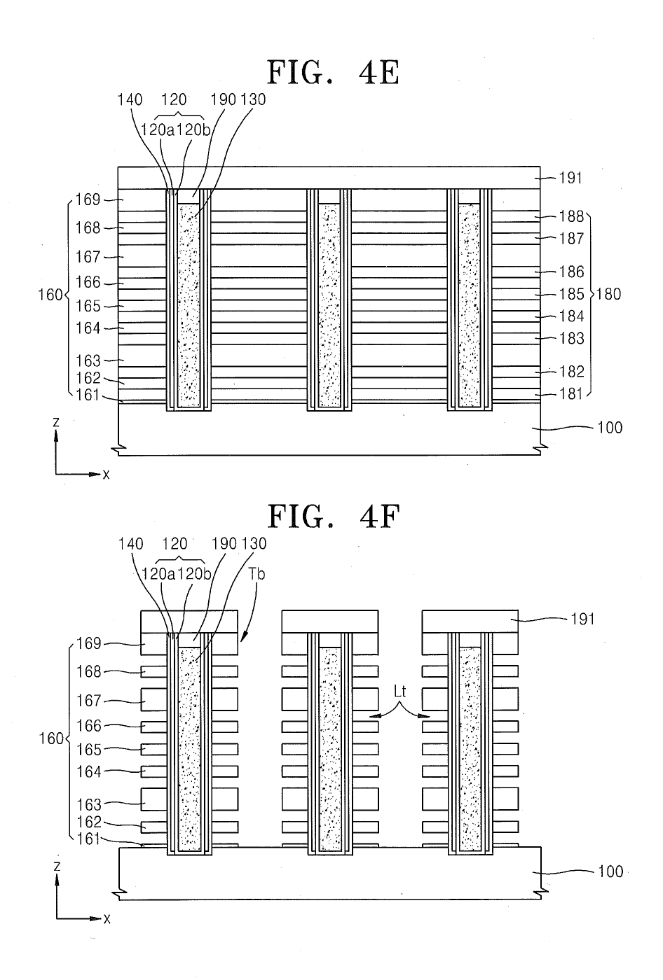

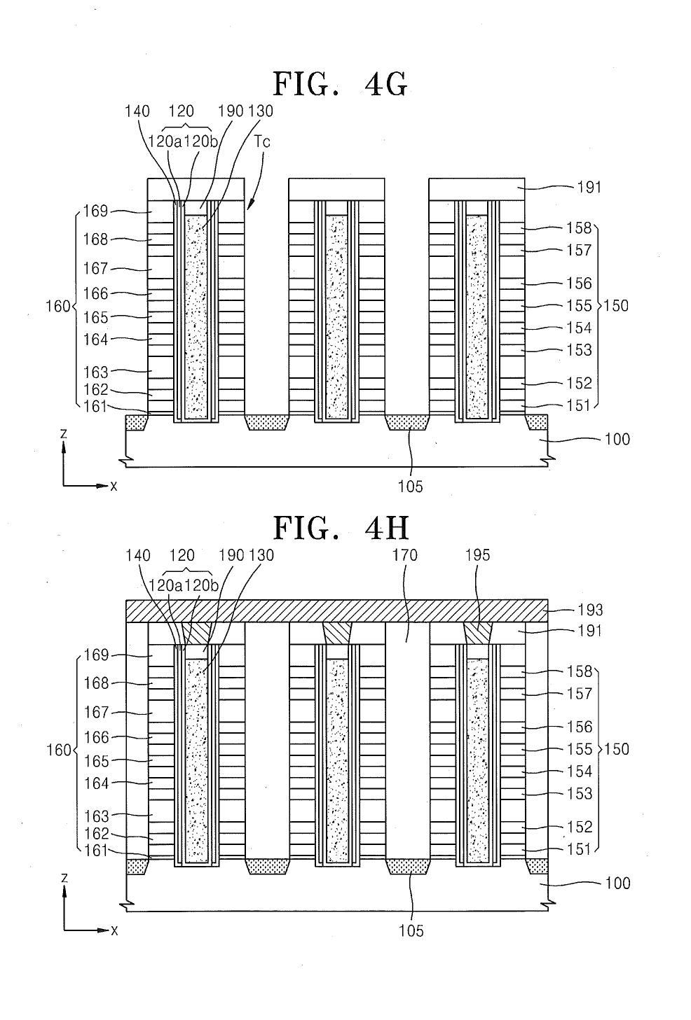

FIGS. 4A through 4H are cross-sectional views for describing methods of manufacturing the non-volatile memory device 1000a of FIG. 3, according to various embodiments described herein, the views as seen in the y-axis direction in FIG. 3.

Referring to FIG. 4A, a plurality of sacrificial layers 181 to 188 (collectively 180), and the interlayer insulating layers 161 to 169 (collectively 160) are alternately stacked on the substrate 100. As illustrated in FIG. 4A, the sacrificial layers 180 and the interlayer insulating layers 160 are alternately stacked from the first interlayer insulating layer 161 on the substrate 100. The sacrificial layers 180 may be folioed of a material that is etched with etch selectivity with respect to the interlayer insulating layers 160. That is, the sacrificial layers 180 may be formed of a material for minimally etching the interlayer insulating layers 160 during the etching of the sacrificial layers 180. The etch selectivity may be quantitatively expressed by a ratio of an etch speed of each sacrificial layer 180 with respect to an etch speed of each interlayer insulating layer 160. For example, the interlayer insulating layer 160 may include a silicon oxide layer and/or a silicon nitride layer. The sacrificial layer 180 may comprise a silicon layer, a silicon oxide layer, a silicon carbide layer and/or a silicon nitride layer, which are different from a material of the interlayer insulating layer 160.

According to various embodiments described herein, as illustrated in FIG. 4A, thicknesses of the interlayer insulating layers 160 may not be the same. The first interlayer insulating layer 161 that is the lowermost of the interlayer insulating layers 160 may have a small thickness, and the third interlayer insulating layer 163 and the seventh interlayer insulating layer 167 may have a large thickness. However, the thicknesses of the interlayer insulating layers 160 and the sacrificial layers 180 may be changed, and the number of layers included in the interlayer insulating layers 160 and the sacrificial layers 180 may also be changed.

Referring to FIG. 4B, first openings Ta may be formed through the interlayer insulating layers 160 and the sacrificial layers 180 which are alternately stacked. The first openings Ta may be holes having a depth in the z-axis direction. In addition, the first openings Ta may be spaced apart from each other in the x-axis and y-axis directions (see FIG. 3), and may be isolated regions.

The first openings Ta may be formed by forming a predetermined mask pattern for defining positions of the first openings Ta on the interlayer insulating layers 160 and the sacrificial layers 180 which are alternately stacked, and then anisotropically etching the interlayer insulating layers 160 and the sacrificial layers 180 by using the predetermined mask pattern as an etching mask. Since a structure including two kinds of different layers is etched, side walls of the first openings Ta may not be exactly perpendicular to an upper surface of the substrate 100. For example, the closer to the substrate 100, the smaller the width of each first opening Ta.

The first opening Ta may expose the upper surface of the substrate 100, as illustrated in FIG. 4B. Furthermore, as a result of over-etching during the anisotropic etching, portions of the substrate 100 below the first openings Ta may be recessed by a predetermined depth, as illustrated in FIG. 4B.

Referring to FIG. 4C, a gate dielectric layer 140 and the first channel layer 120a may be formed so as to uniformly cover inner walls and lower surfaces of the first openings Ta.

The gate dielectric layer 140 may include a blocking insulating layer 146, a charge storage layer 144, and a tunneling insulating layer 142. Thus, in the order stated above, the blocking insulating layer 146, the charge storage layer 144, and the tunneling insulating layer 142 may be sequentially stacked in the first openings Ta. The blocking insulating layer 146, the charge storage layer 144, and the tunneling insulating layer 142 may be formed by using an atomic layer deposition (ALD) method, a chemical vapor deposition (CVD) method and/or a physical vapor deposition (PVD) method.

Then, the first channel layer 120a may be formed by using the ALD and/or CVD method. The first channel layer 120a may be formed in a predetermined thickness, for example, a half or less of the thickness of the channel region 120 (see FIG. 3).

Referring to FIG. 4D, portions of the gate dielectric layer 140 and portions of the first channel layer 120a, which correspond to bottom surfaces of the first openings Ta, are etched so as to expose the substrate 100. The portions may be etched by anisotropically etching the first channel layer 120a and etching the gate dielectric layer 140 by using the first channel layer 120a of which a lower surface is etched in the form of a space. Although not illustrated in FIG. 4D, as a result of over-etching during the anisotropic etching, portions of the substrate 100 below the first openings Ta may be recessed by a predetermined depth.

Alternatively, the anisotropic etching may be performed after the gate dielectric layer 140 is formed, before the first channel layer 120a is formed. In this case, the first channel layer 120a is formed so as to contact the substrate 100, and the second channel layer 120b may be omitted.

Then, the second channel layer 120b may be formed so as to uniformly cover the inner walls and lower surfaces of the first openings Ta. The second channel layer 120b may be formed of the same material as that of the first channel layer 120a, and may include, for example, a semiconductor material such as non-doped polysilicon or single crystalline silicon. The second channel layer 120b is formed so as to contact the substrate 100, and is electrically connected to the substrate 100. The second channel layer 120b and the first channel layer 120a constitute the channel region 120. Although the channel region 120 may not include impurities in the current process, the channel region 120 may include impurities through subsequent processes.

Referring to FIG. 4E, the impurity providing layer 130 may be formed so as to fill the first opening Ta. The impurity providing layer 130 may be formed of an insulating material including impurities such as a group III and/or V element in order to provide impurities to the channel region 120. The impurities may be, for example, n-type impurities such as phosphorus (P), arsenic (As) and/or antimony (Sb), or p-type impurities such as boron (B), aluminum (Al), gallium (Ga) and/or zinc (Zn). For example, the impurity providing layer 130 may include phosphosilicate glass (PSG) and/or borosilicate glass (BSG). The impurity providing layer 130 may have an impurity concentration of, for example, from about 10¹⁶/cm³ to about 10²¹/cm³. According to a modified embodiment, by performing ion implantation prior to the forming of the impurity providing layer 130 on the channel region 120, impurities may be initially included in the channel region 120.

Then, in order to remove semiconductor materials and insulating materials which cover the ninth interlayer insulating layer 169, a planarization process, for example, chemical mechanical polishing (CMP) or etch-back may be performed until the ninth interlayer insulating layer 169 is exposed.

Upper portions of the impurity providing layer 130 are removed, and then a conductive material for forming the conductive layer 190 may be deposited on portions corresponding to the removed upper portions of the impurity providing layer 130. By performing planarization, the conductive layer 190 that is disposed on the impurity providing layer 130 and is connected to the channel region 120 may be formed. Then, etch barriers 191 may be formed on the ninth insulating layer 169.

Impurities included in the impurity providing layer 130 may diffuse into the channel region 120 while high-temperature processes are performed during subsequent processes. In addition or instead, after the impurity providing layer 130 is formed, a separate heat-treatment process may be performed so that impurities may be diffused. The heat-treatment process may be performed at a temperature of about 600° C. to about 1200° C. for several seconds to several tens of minutes.

Referring to FIG. 4F, second openings Tb may be formed so as to expose upper surfaces of the substrate 100. The second openings Tb may extend in the y-axis direction (see FIG. 3). The second openings Tb may be formed by forming an etch mask for defining the second openings Tb, and anisotropically etching portions of the interlayer insulating layers 160 and portions of the sacrificial layers 180 below the etch mask until the upper surfaces of the substrate 100 are exposed.

According to various embodiments described herein, each second opening Tb may be formed between the channel regions 120. However, various embodiments described herein are not limited thereto. That is, relative arrangement of the channel region 120 and the second openings Tb may be changed.

Then, portions of the sacrificial layers 180 (see FIG. 4E), which are removed through the second openings Tb, are selectively removed. The portions of the sacrificial layers 180 are removed so as to form a plurality of tunnels Lt connected to the second openings Tb and having a horizontal shape between the interlayer insulating layers 160 with respect to the substrate 100, and parts of side walls of the gate dielectric layer 140 may be exposed through the tunnels Lt.

The tunnels Lt may be formed by horizontally etching the sacrificial layers 180 by using an etchant having etch selectivity with respect to the interlayer insulating layers 160. For example, when the sacrificial layers 180 is a silicon nitride layer, and the interlayer insulating layers 160 is a silicon oxide layer, the horizontally etching may be performed using an etchant including phosphoric acid. The etching may be anisotropic etching including wet etching and/or chemical dry etch (CDE).

Referring to FIG. 4G the second openings Tb and the tunnels Lt of FIG. 4F may be filled by a conductive material. Then, the conductive material is etched to form third openings Tc having substantially the same width and position as the second openings Tb so as to expose the substrate 100. Thus, the gate electrodes 151 to 158 (collectively 150) may be formed so as to surround the channel region 120.

Impurities may be injected into the substrate 100 through the third openings Tc to form the impurity regions 105 that are adjacent to the upper surface of the substrate 100 and extend in the y-axis direction (see FIG. 3). The impurities regions 105 may be heavily-doped impurity regions which are formed by injecting N+ type impurities. A process for forming the impurity regions 105 does not have to be currently performed, and may be performed in previous processes or subsequent processes, if desired.

Referring to FIG. 4H, insulating regions 170 may be formed so as to fill the third openings Tc. The insulating regions 170 may be formed of the same material as that of the interlayer insulating layers 160. The insulating regions 170 may be formed by depositing and polarizing an insulating material.

Then, bit line contact plugs 195 may be formed through the etch barriers 191 on the conductive layer 190. The bit line contact plugs 195 may be formed by using a photolithography process and an etching process. A bit line 193 connecting the bit line contact plugs 195 arranged in the x-axis direction may be formed on the etch barriers 191 and the insulating regions 170. The bit line 193 may also be formed in a line shape by using the photolithography process and the etching process.

Accordingly, FIGS. 3-4G illustrate a vertical transistor structure according to various embodiments described herein that comprises a substrate 100 including a horizontal surface and a column 130 on the substrate that extends vertically away from the horizontal surface that includes a wall that extends vertically away from the horizontal surface. A channel region 120 is provided on the wall of the column 130. The channel region also extends vertically away from the horizontal surface of the substrate 100. A gate dielectric 140 is provided on the channel region 120 opposite the column 130. The gate dielectric also extends vertically away from the horizontal surface of the substrate 100. A plurality of gate electrodes 150 are stacked upon one another on the horizontal surface of the substrate 100. The plurality of gate electrodes extend adjacent the gate dielectric 140 opposite the channel region 120. Moreover, the column 130 is more heavily doped with impurities than the channel region 120. The column 130 may be a solid column 130 that is doped with the impurities.

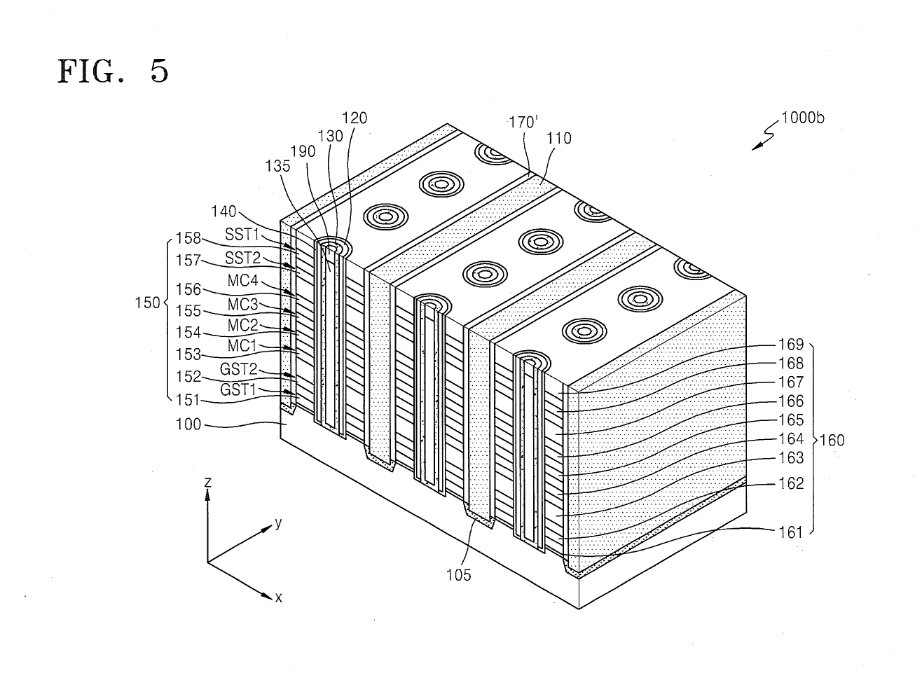

FIG. 5 is a schematic perspective view of a 3D structure of memory cell strings of a non-volatile memory device 1000b according to various other embodiments described herein.

In FIGS. 3 and 5, like reference numerals refer to like elements and, thus, the detailed description thereof will be omitted. Referring to FIG. 5, the non-volatile memory device 1000b may include an impurity providing layer 130 and an embedded insulating layer 135, which are disposed in the channel region 120. The channel region 120 may be electrically connected to the substrate 100 through the impurity providing layer 130.

Unlike in FIG. 3, the impurity providing layer 130 may be formed of a semiconductor material including impurities, for example, doped polysilicon. In addition, the impurity providing layer 130 may be formed to a thickness so as not to fill an internal portion of the channel region 120. Stated differently, in FIG. 5, the column is a hollow column that is doped with the impurities. Before polysilicon doped using a general process is diffused, the polysilicon has an impurity concentration of about 10²⁰/cm³. Thus, in order to change the impurity concentration of the channel region 120 to a desired impurity concentration, for example, about 10¹⁹/cm³ or less, impurities may be diffused from the impurity providing layer 130 to the channel region 120. An amount of impurities diffused to the channel region 120 may be controlled according to a thickness and a time for heat-treatment of the impurity providing layer 130. When the amount of impurities diffused to the channel region 120 is controlled according to the time for heat-treatment, impurities may be diffused using a subsequent high-temperature process. However, when an amount of diffused impurities is not sufficient, a separate heat-treatment may be used so as to control a concentration of impurities in the channel region 120.

The embedded insulating layer 135 may fill the impurity providing layer 130, and may include an insulating material. Alternatively, the embedded insulating layer 135 may also be formed of an insulating material including impurities.

The impurity providing layer 130 and the embedded insulating layer 135 may be manufactured by forming the gate dielectric layer 140 and the channel region 120, anisotropically etching the gate dielectric layer 140 and the channel region 120, in the manufacturing method described with reference to FIG. 4D, and then depositing materials for forming the impurity providing layer 130 and the embedded insulating layer 135.

In the non-volatile memory device 1000b, a common source line 110 may extend in the z-axis direction on the impurity regions 105, and may ohmic-contact the impurity regions 105. The common source line 110 may provide a source region to ground selection transistors GST1 and GST2 of memory cell strings of lateral surfaces of two channel regions 120 that are adjacent in the x-axis direction. The common source line 110 may extend in the y-axis direction along the impurity regions 105. The common source line 110 may include a conductive material. For example, the common source line 110 may include at least one metal material selected from tungsten (W), aluminum (Al) and/or copper (Cu). Although not illustrated in FIG. 5, a silicide layer for reducing a contact resistance may be interposed between the impurity regions 105 and the common source line 110. The silicide layer (not shown) may include a metal silicide layer, for example, a cobalt silicide layer.

When the impurity regions 105 have an opposite conductivity type to that of the substrate 100, the impurity regions 105 may be source regions of the ground selection transistors GST1 and GST2. When the impurity regions 105 have the same conductive type as that of the substrate 100, the common source line 110 may function as a pocket P well contact electrode for a removing operation of a memory cell block unit. In this case, data stored in all memory cells in a corresponding memory cell block of the substrate 100 may be erased by applying a high voltage to the substrate 100 through the pocket P well contact electrode.

The common source line 110 may be formed by forming the insulating regions 170, forming spacer insulating regions 170′ on side wall of the third openings Tc and then depositing an insulating material for forming the common source line 110. The spacer insulating regions 170′ may be formed by filling an insulating material in the third openings Tc and then performing anisotropic etching. By the anisotropic etching, the substrate 100 may be over-etched, and thus the substrate 100 may be recessed. Then, a deposition process of a conductive material and an etching process such as etch-back may be further performed so as to form the common source line 110.

In the non-volatile memory device 1000b, the channel region 120 having a desired impurity concentration may be formed by using the impurity providing layer 130 including a doped semiconductor material.

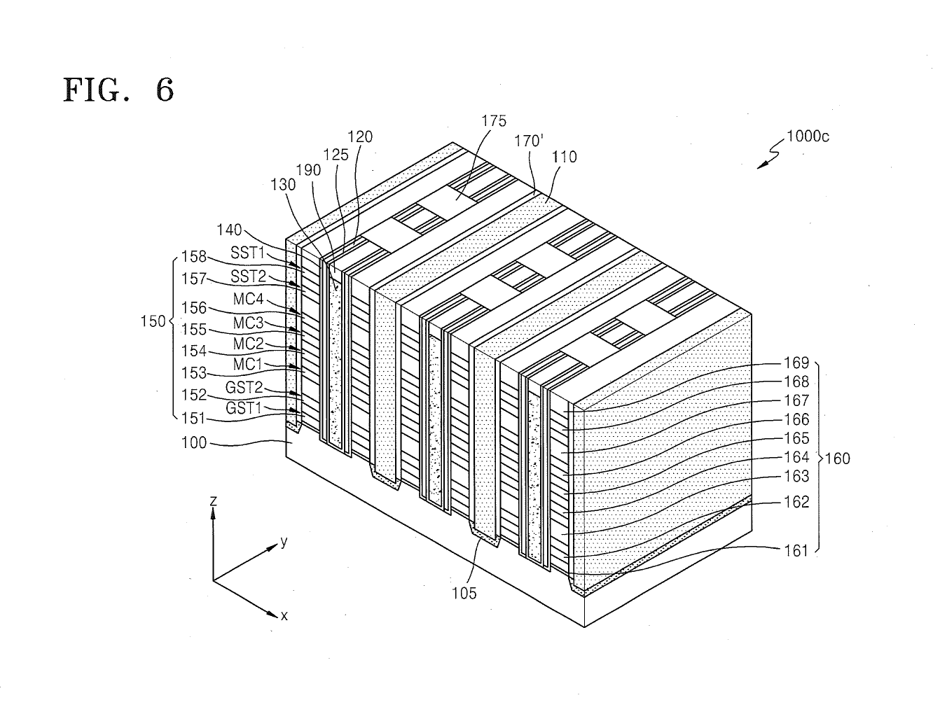

FIG. 6 is a schematic perspective view of a 3D structure of memory cells strings of a non-volatile memory device 1000c according to various other embodiments described herein.

In FIGS. 3 and 5, like reference numerals refer to like elements and, thus, the detailed description thereof will be omitted. Referring to FIG. 6, the non-volatile memory device 1000c may further include a diffusion controlling layer 125 disposed between the channel region 120 and the impurity providing layer 130, unlike in FIG. 3. The channel region 120 may be electrically connected to the substrate 100 through the diffusion controlling layer 125. According to a modified embodiment, the channel region 120 may include at least two channel layers, like in FIG. 3. In this case, the channel region 120 may be connected directly to the substrate 100 without through the diffusion controlling layer 125.

The diffusion controlling layer 125 controls an amount of impurities that are diffused from the impurity providing layer 130 to the channel region 120. The diffusion controlling layer 125 stops and accelerates diffusion of impurities in order to form the channel region 120 with a desired impurity concentration. The diffusion controlling layer 125 may function as, for example, a diffusion barrier, and may reduce a diffusion speed of impurities. The diffusion controlling layer 125 may include any one selected from tungsten nitride (WN), tantalum nitride (TaN) and/or titanium nitride (TiN). Accordingly, embodiments illustrated in FIG. 6 can comprise a diffusion controlling layer 125 between the channel region 120 and the column 130, that extends vertically away from the horizontal surface of the substrate 100 and that is configured to reduce, but not block, diffusion of the impurities from the column 130 to the channel region 120.

The impurity providing layer 130 may be formed of an insulating material including impurities such as a group III or V element. For example, the impurity providing layer 130 may include PSG and/or BSG According to a modified embodiment, the impurity providing layer 130 may include a semiconductor material including impurities, for example, doped polysilicon.

The diffusion controlling layer 125 may be formed by forming the gate dielectric layer 140 and the channel region 120 and then depositing a material for forming the diffusion controlling layer 125 prior to the forming of the impurity providing layer 130, in the manufacturing method described with reference to FIG. 4D.

In the non-volatile memory device 1000c, the common source line 110 may extend in the z-axis direction on the impurity regions 105 and may ohmic-contact the impurity regions 105, like in FIG. 5.

According to embodiments of FIG. 6, unlike in FIGS. 3 and 5, insulating layers 175 may be arranged between the channel regions 120 that are arranged in the y-axis direction. Thus, two memory cell strings extending the z-axis direction may be arranged along two lateral surfaces of the x-axis direction of a single channel region 120.

In the non-volatile memory device 1000c, an amount of diffused impurities may be further controlled by disposing the diffusion controlling layer 125 between the impurity providing layer 130 and the channel region 120.

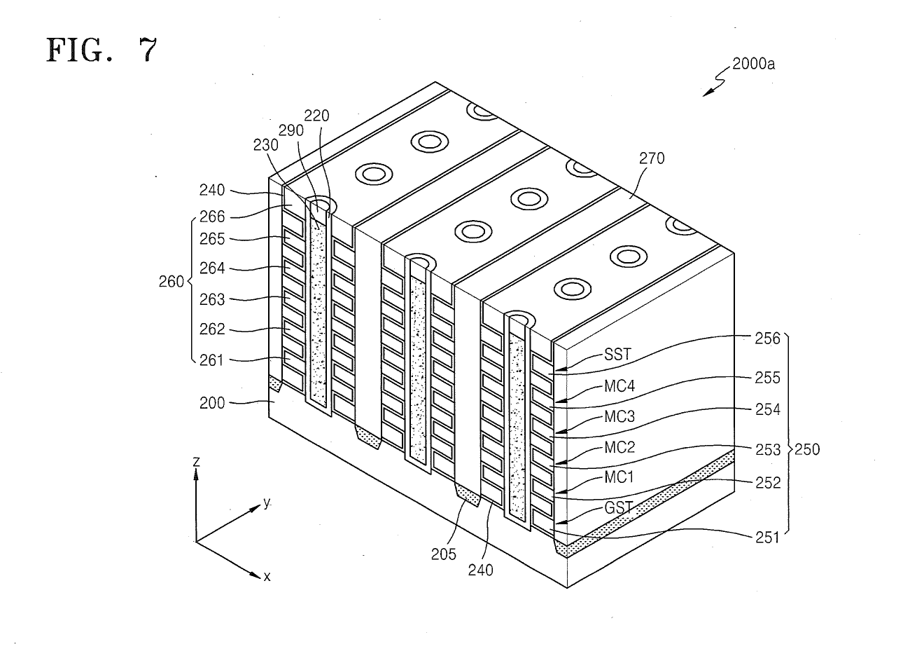

FIG. 7 is a schematic perspective view of a 3D structure of memory cells strings of a non-volatile memory device 2000a according to various other embodiments described herein.

In FIG. 7, some components of the memory cell strings 11 of FIG. 1 are omitted. For example, bit lines of the memory cell strings 11 of FIG. 1 are omitted.

Referring to FIG. 7, the non-volatile memory device 2000a includes a plurality of channel regions 220 disposed on a substrate 200, and a plurality of memory cell strings that are respectively arranged along walls of the channel regions 220.

The substrate 200 may have a main horizontal surface that extends in the x-axis and y-axis directions. The substrate 200 may include a semiconductor material, for example, a group IV semiconductor, a group III to V compound semiconductor and/or a group II to VI oxide semiconductor. For example, examples of the group IV semiconductor may include silicon (Si), germanium (Ge), or Si—Ge. The substrate 200 may be a bulk wafer or an epitaxial layer.

Each channel region 220 having a column shape may be disposed on the substrate 200 so as to extend in the z-axis direction. The channel regions 220 may be spaced apart from each other in the x-axis and y-axis directions. The channel region 220 may be formed, for example, in an annular shape. A bottom surface of the channel region 220 directly contacts the substrate 200 so as to be electrically connected thereto. The channel region 220 may include a semiconductor material such as polysilicon or single crystalline silicon, and the semiconductor material may include p-type or n-type impurities.

An impurity providing layer 230 may be disposed in the channel region 220. The impurity providing layer 230 may be formed of an insulating material including impurities such as a group III element or a group V element in order to provide impurities to the channel region 220. The impurities may include, for example, n-type impurities such as phosphorus (P), arsenic (As) and/or antimony (Sb), or p-type impurities such as boron (B), aluminum (Al), gallium (Ga) and/or zinc (Zn). For example, the impurity providing layer 130 may include PSG and/or BSG The impurity providing layer 230 may have a higher impurity concentration than that of the channel region 220, and the impurities may diffuse into the channel region 220 by heat applied during the manufacture of the non-volatile memory device 2000a.

A conductive layer 290 covers an upper surface of the impurity providing layer 230, and is electrically connected to the channel region 220. The conductive layer 290 may include doped polysilicon. The conductive layer 290 may function as a drain region of the string selection transistor SST.

The string selection transistors SST arranged in the x-axis direction may be commonly connected to the bit lines BL (see FIG. 1) through conductive layers 290. The bit lines (not shown) may each have a pattern having a line shape extending in the x-axis direction, and may be electrically connected to the conductive layer 290 through a contact electrode (not shown) formed on the conductive layer 290. In addition, the ground selection transistors GST extending in the x-axis direction are electrically connected to impurity regions 205 adjacent thereto.

The impurity regions 205 may be adjacent to the main surface of the substrate 200, extend in the y-axis direction, and may be spaced apart from each other in the x-axis direction. The impurity regions 205 and the channel regions 220 may be alternately arranged in the x-axis direction. The impurity regions 205 may be source regions, and may form a PN junction with another region of the substrate 200. The common source line CSL of FIGS. 1 and 2 may be connected to the impurity regions 205 on a region that is not shown. Insulating regions 270 may be respectively formed on the impurity regions 205.

Each insulating region 270 may be formed between the channel regions 220. That is, the insulating region 270 may be formed between adjacent memory cell strings using different channel regions 220.

A plurality of gate electrodes 251 to 256 (collectively 250) may be may be spaced apart from each other in the z-axis direction from the substrate 200 along the lateral walls of the channel region 220. The gate electrodes 250 may be gate electrodes of the ground selection transistor GST, a plurality of memory cells MC1, MC2, MCn-1 and MCn, and the string selection transistor SST. The gate electrodes 250 may be commonly connected to memory cell strings that are adjacent in the y-axis direction.

A gate dielectric layer 240 may be disposed between the channel region 120 and the gate electrodes 250. The gate dielectric layer 240 may be disposed so as to cover upper and lower surfaces of the gate electrodes 250. In addition, the gate dielectric layer 240 may cover one lateral surface of each interlayer insulating layer 260 so as not to contact the channel region 220. Although not illustrated in FIG. 7, the gate dielectric layer 240 may include a tunneling insulating layer, a charge storage layer, and a blocking insulating layer, which are sequentially stacked from the channel region 220.

A plurality of interlayer insulating layers 261 to 266 (collectively 260) may be disposed between the gate electrodes 250. The interlayer insulating layers 260 may be spaced apart from each other in the z-axis direction, and may extend in the y-axis direction, like the gate electrodes 250. One side of each interlayer insulating layer 260 may contact the gate dielectric layer 240. The interlayer insulating layers 260 may include silicon oxide or silicon nitride.

In the non-volatile memory device 2000a having a 3D vertical structure according to various embodiments described herein, while it is difficult to uniformly dope the channel region 220 with impurities by ion-implantation due to a high aspect ratio of the channel region 220, impurities may be uniformly provided to the channel region 220 by the impurity providing layer 230. Thus, threshold voltages of a memory cell and a selection transistor can be controlled, and the characteristics of a memory cell string, such as cell string current characteristics, can be controlled.

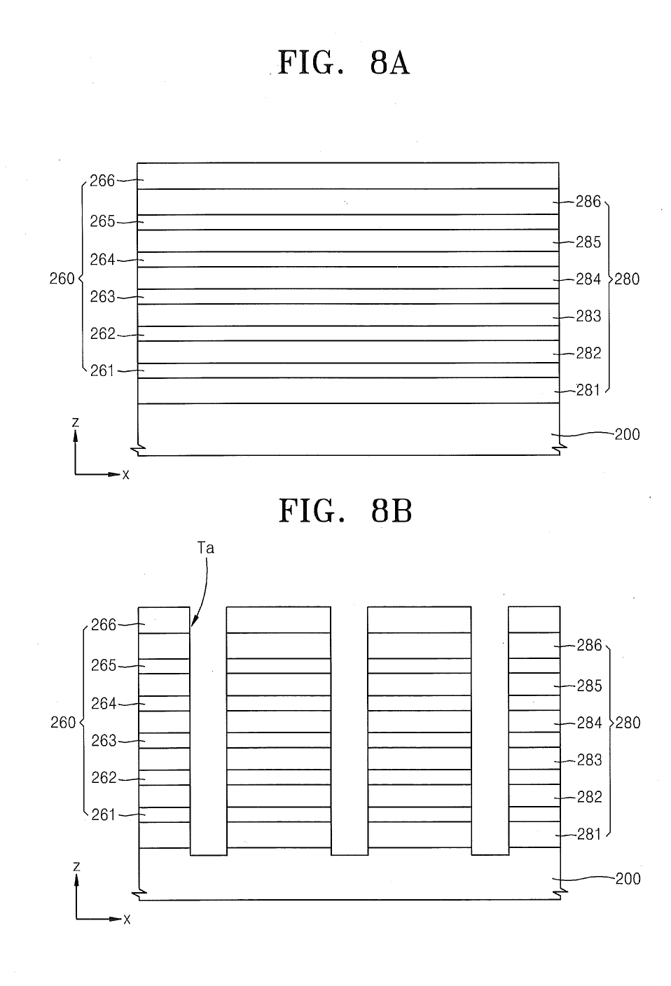

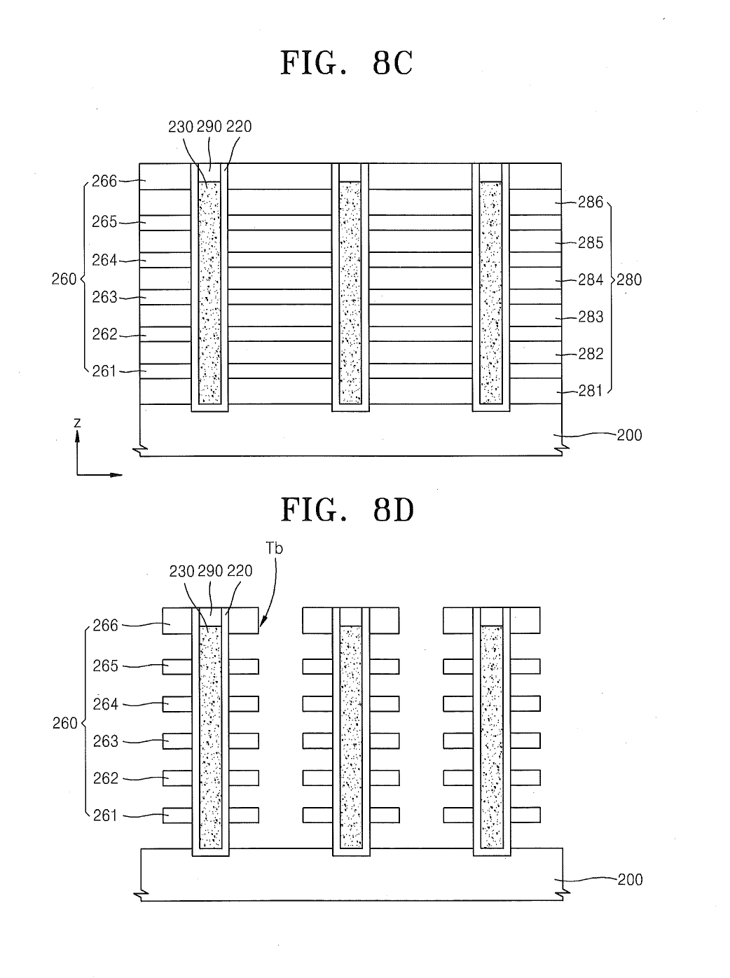

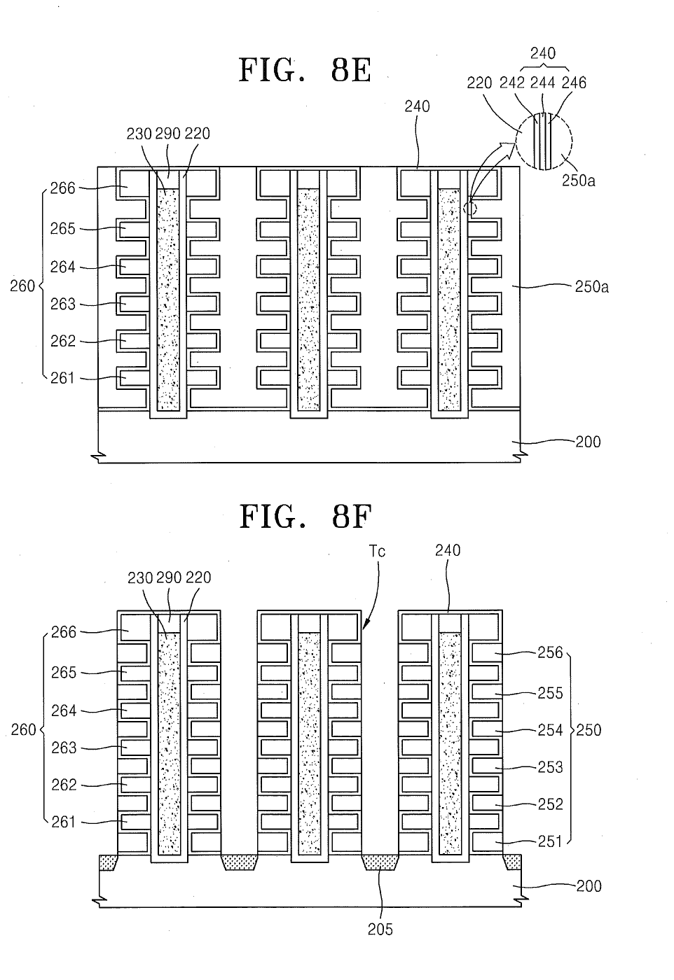

FIGS. 8A through 8F are cross-sectional views for describing methods of manufacturing the non-volatile memory device 2000a of FIG. 7, according to various embodiments described herein, the views as seen in the y-axis direction in FIG. 7.

Referring to FIG. 8A, a plurality of sacrificial layers 281 to 286 (collectively 280), and the interlayer insulating layers 261 to 266 (collectively 1600 are alternately stacked on the substrate 200. The interlayer insulating layers 260 and the sacrificial layers 280 may be formed of material having etch selectivity with respect to each other.

Referring to FIG. 8B, first openings Ta may be formed through the interlayer insulating layers 260 and the sacrificial layers 280 so as to expose the substrate 200. The first openings Ta may be arranged in a matrix form in the x-axis and y-axis directions so as to correspond to regions where the channel regions 220 (see FIG. 8C) and the impurity providing layers 230 (see FIG. 8C) are to be formed in subsequent processes, as illustrated in FIG. 7.

Referring to FIG. 8C, the channel region 220 may be formed so as to uniformly cover inner walls and lower surfaces of the first openings Ta of FIG. 8B. The channel region 220 may be formed to a predetermined thickness, for example, 1/50 to ⅕ of a width of each first opening Ta by using an ALD and/or CVD method.

Then, the first openings Ta may be filled with the impurity providing layer 230. Alternatively, prior to the forming of the impurity providing layer 230, a hydrogen annealing process of performing heat-treatment on a structure including the channel region 220 under an atmosphere including hydrogen and/or heavy hydrogen may be further performed. By the hydrogen annealing process, many defects of the channel region 220 may be reduced.

Then, in order to remove semiconductor materials and insulating materials which cover the ninth interlayer insulating layer 266, a planarization process may be performed. Upper portions of the impurity providing layer 230 are removed using an etching process, and a material for forming the conductive layer 290 may be deposited on portions corresponding to the removed upper portions of the impurity providing layer 230. By performing planarization, the conductive layer 290 may be formed.

Impurities included in the impurity providing layer 230 may diffuse into the channel region 220 while high-temperature processes are performed during subsequent processes. In addition or instead, after the impurity providing layer 230 is formed, a separate heat-treatment process may be performed so that impurities may be diffused.

Referring to FIG. 8D, second openings Tb may be formed so as to expose upper surfaces of the substrate 200. The second openings Tb may extend in the y-axis direction (see FIG. 7).

The second openings Tb may be formed by anisotropically etching the interlayer insulating layers 260 and the sacrificial layers 280 (see FIG. 8C) by using a photolithography process. The second openings Tb extend in the y-axis direction so as to correspond to regions where the insulating regions 270 are to be formed in subsequent processes. Portions of the sacrificial layers 280, which are exposed through the second openings Tb, may be removed so as to form a plurality of tunnels Lt that are defined above and below the interlayer insulating layers 260. Some lateral walls of the channel regions 220 may be exposed through the tunnels Lt.

Referring to FIG. 8E, the gate dielectric layer 240 may be formed so as to uniformly cover the portions of the channel region 220, the interlayer insulating layers 260 and the substrate 200, which are exposed through the second openings Tb and the tunnels Lt in FIG. 8D.

The gate dielectric layer 240 may include a tunneling insulating layer 242, a charge storage layer 244 and a blocking insulating layer 246, which are sequentially stacked from the channel region 220. Then, the second openings Tb and the tunnels Lt may be filled with a conductive material 250a.

Referring to FIG. 8F, the conductive material 250a of FIG. 8E is partially etched to form third openings Tc. Thus, the conductive material 250a may fill only internal portions of the tunnels Lt of FIG. 8E so as to form the gate electrodes 250. The above-process is performed by anisotropic etching and the gate dielectric layer 240 formed on the substrate 200 may also be removed. Alternatively, the gate dielectric layers 240 formed on lateral surfaces of the interlayer insulating layers 260 may also be removed. Then, impurities may be injected into the substrate 200 through the third openings Tc so as to form the impurity regions 205.

Then, the process described with reference to FIG. 4H is performed so as to manufacture the non-volatile memory device 2000a of FIG. 7.

Accordingly, FIGS. 7-8F illustrate a vertical transistor structure according to various embodiments described herein that comprises a substrate 200 including a horizontal surface and a column 230 on the substrate that extends vertically away from the horizontal surface that includes a wall that extends vertically away from the horizontal surface. A channel region 220 is provided on the wall of the column 230. The channel region also extends vertically away from the horizontal surface of the substrate 200. A gate dielectric 240 is provided on the channel region 220 opposite the column 230. The gate dielectric also extends vertically away from the horizontal surface of the substrate 200. A plurality of gate electrodes 250 are stacked upon one another on the horizontal surface of the substrate 200. The plurality of gate electrodes extend adjacent the gate dielectric 240 opposite the channel region 220. Moreover, the column 230 is more heavily doped with impurities than the channel region 220. The column 230 may be a solid column 230 that is doped with the impurities.

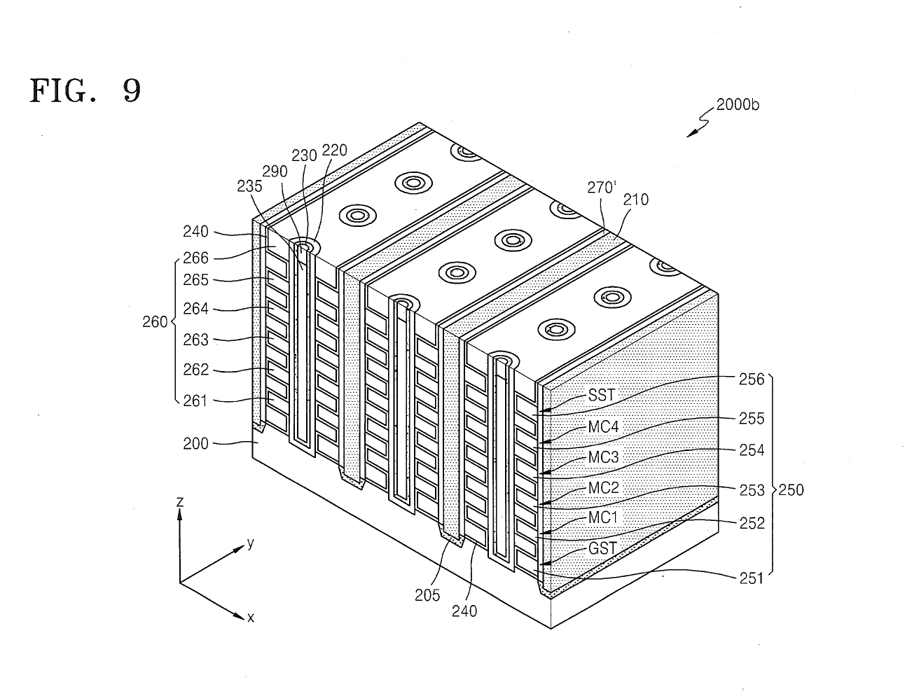

FIG. 9 is a schematic perspective view of a 3D structure of memory cells strings of a non-volatile memory device 2000b according to various embodiments described herein.

In FIGS. 7 and 9, like reference numerals refer to like elements and, thus, the detailed description thereof will be omitted. Referring to FIG. 9, the non-volatile memory device 2000b may include the impurity providing layer 230 and an embedded insulating layer 235, which are disposed in the channel region 220.

Unlike in FIG. 7, the impurity providing layer 230 may be formed of a semiconductor material including impurities, for example, doped polysilicon. In addition, the impurity providing layer 230 may be formed to a thickness so as not to fill an internal portion of the channel region 220. Stated differently, in FIG. 5, the column 230 is a hollow column that is doped with the impurities. Before polysilicon doped using a general process is diffused, the polysilicon has an impurity concentration of about 10²⁰/cm³. Thus, in order to change the impurity concentration of the channel region 120 to a desired impurity concentration, for example, about 10¹⁹/cm³ or less, impurities may be diffused from the impurity providing layer 230 to the channel region 220. An amount of impurities diffused to the channel region 220 may be controlled according to a thickness and a time for heat-treatment of the impurity providing layer 230. When the amount of impurities diffused to the channel region 220 is controlled according to the time for heat-treatment, impurities may be diffused using a subsequent high-temperature process. However, when an amount of diffused impurities is not sufficient, a separate heat-treatment may be used so as to control a concentration of impurities in the channel region 220.

The embedded insulating layer 235 may fill the impurity providing layer 230, and may include an insulating material. Alternatively, the embedded insulating layer 235 may also be formed of an insulating material including impurities.

The impurity providing layer 230 and the embedded insulating layer 235 may be manufactured by forming the channel region 220 and then sequentially forming the impurity providing layer 230 and the embedded insulating layer 235, in the manufacturing method described with reference to FIG. 8C.

In the non-volatile memory device 2000b, a common source line 210 may extend in the z-axis direction on each of the impurity regions 205, and may ohmic-contact the impurity regions 205. The common source line 210 may provide a source region to the ground selection transistors GST of memory cell strings of lateral surfaces of two channel regions 220 that are adjacent in the x-axis direction. The common source line 210 may include at least one metal material selected from tungsten (W), aluminum (Al) and/or copper (Cu). Although not illustrated in FIG. 9, a silicide layer for reducing a contact resistance may be interposed between the impurity regions 205 and the common source line 210. The silicide layer (not shown) may include a metal silicide layer, for example, a cobalt silicide layer.

In the non-volatile memory device 2000b, the channel region 220 having a desired impurity concentration may be formed by using the impurity providing layer 230 including a doped semiconductor material.

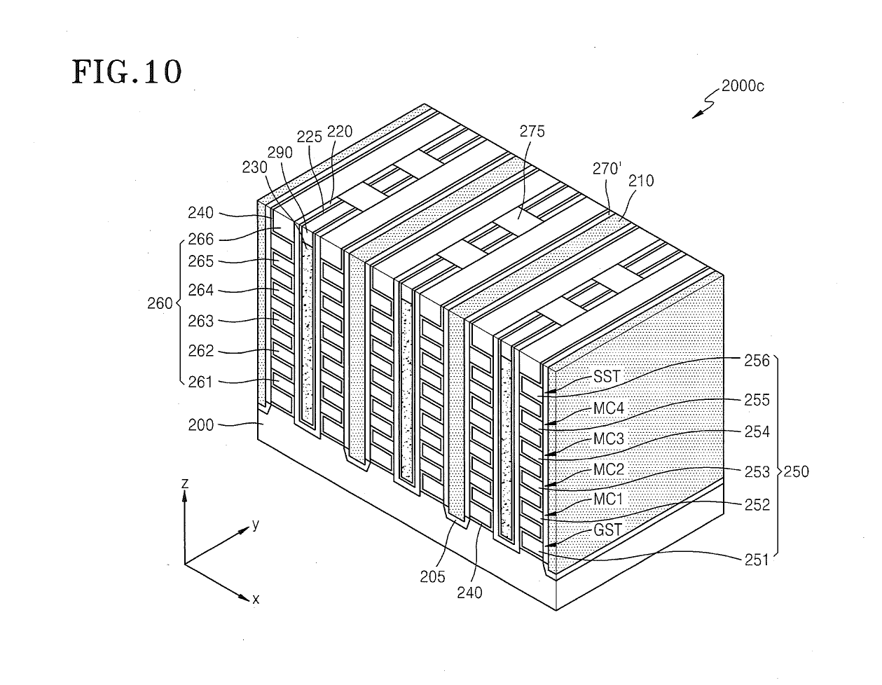

FIG. 10 is a schematic perspective view of a 3D structure of memory cells strings of a non-volatile memory device 2000c according to various other embodiments described herein.

In FIGS. 7 and 9, like reference numerals refer to like elements and, thus, the detailed description thereof will be omitted. Referring to FIG. 10, the non-volatile memory device 2000c may further include a diffusion controlling layer 225 disposed between the channel region 220 and the impurity providing layer 230, unlike in FIG. 7.

The diffusion controlling layer 225 controls an amount of impurities that are diffused from the impurity providing layer 230 to the channel region 220. The diffusion controlling layer 225 stops and accelerates diffusion of impurities in order to form the channel region 220 with a desired impurity concentration. The diffusion controlling layer 225 may function as, for example, a diffusion barrier, and may reduce a diffusion speed of impurities. The diffusion controlling layer 225 may include any one selected from tungsten nitride (WN), tantalum nitride (TaN) and/or titanium nitride (TiN). Accordingly, embodiments illustrated in FIG. 10 can comprise a diffusion controlling layer 225 between the channel region 220 and the column 230, that extends vertically away from the horizontal surface of the substrate 200 and that is configured to reduce, but not block, diffusion of the impurities from the column 230 to the channel region 220.

The impurity providing layer 230 may be formed of an insulating material including impurities such as a group III or V element. For example, the impurity providing layer 230 may include PSG and/or BSG According to a modified embodiment, the impurity providing layer 230 may include a semiconductor material including impurities, for example, doped polysilicon.

The diffusion controlling layer 225 may be formed by forming the channel region 220 and then depositing a material for forming the diffusion controlling layer 225 prior to the forming of the impurity providing layer 230, in the manufacturing method described with reference to FIG. 8C.

In the non-volatile memory device 2000c, the common source line 210 may extend in the z-axis direction on the impurity regions 205 and may ohmic-contact the impurity regions 205, like in FIG. 9.

According to embodiments of FIG. 10, unlike in FIGS. 7 and 9, insulating layers 275 may be arranged between the channel regions 220 that are arranged in the y-axis direction. Thus, two memory cell strings extending the z-axis direction may be arranged along two lateral surfaces of a single channel region 220 in the x-axis direction.

In the non-volatile memory device 2000c, an amount of diffused impurities may be further controlled by disposing the diffusion controlling layer 225 between the impurity providing layer 230 and the channel region 220.

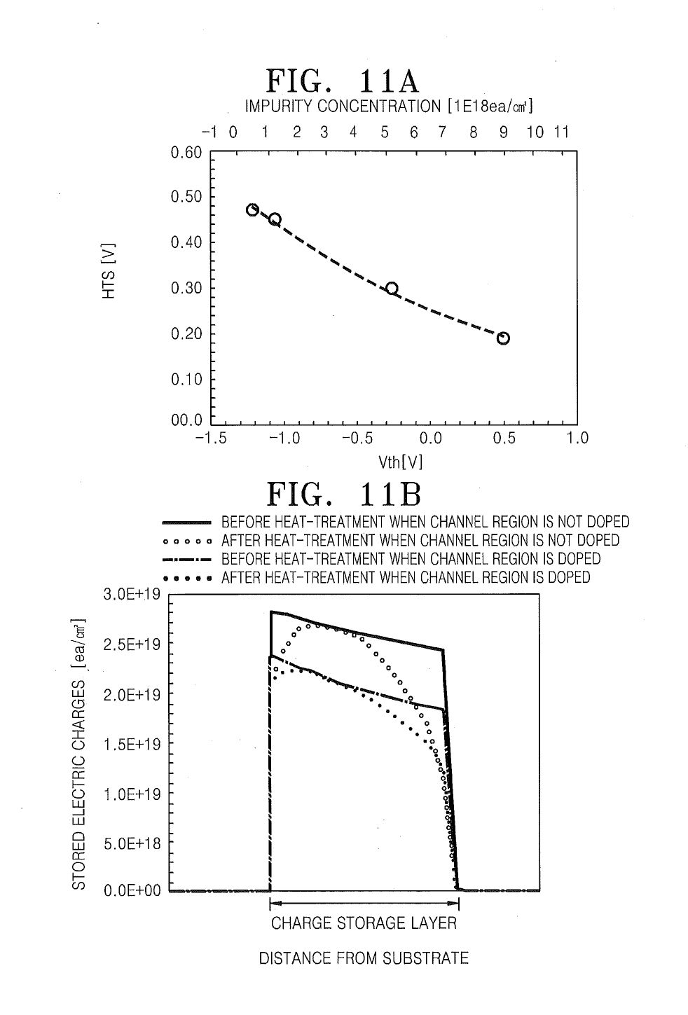

FIGS. 11A and 11B are graphs showing simulation results of hot temperature stress (HTS) characteristics of a non-volatile memory device, according to various embodiments described herein.

FIG. 11A shows HTS characteristics according to an impurity concentration and threshold voltage of a channel region of a memory cell transistor. The HTS is a method of estimating characteristics of a device by measuring a change in electric charges before/after high-temperature heat-treatment is performed by using a transition in a threshold voltage (Vₜₕ). The transition in the threshold voltage (Vₜₕ) is an amount of electric charges that are leaked by the high-temperature heat-treatment. The smaller the transition in the threshold voltage (Vₜₕ), the better the characteristics of a device. The results are obtained by performing a recording operation on non-volatile memory devices and simulating the transition in the threshold voltage (Vₜₕ) after the non-volatile memory devices are baked at a temperature of 200° C.

In FIG. 11A, the higher an impurity concentration of a channel region, the higher the threshold voltage (Vₜₕ), and the HTS characteristics may be improved. When the channel region has an impurity concentration of about 9×10¹⁸/cm³, the transition of the threshold voltage (Vₜₕ) improved from about 0.47 V to about 0.19 V by 59%. In this case, the threshold voltage (Vₜₕ) was increased from −1.3 V to about 0.5 V by about 1.8 V. In order to increase a threshold voltage, a desired concentration of impurities needs to be close to 10¹⁹/cm³.

FIG. 11B shows an amount of electric charges stored in a charge storage layer according to a thickness of a charge storage layer before/after heat-treatment is performed. When the channel region does not include any impurity, a large amount of electric charges are trapped prior to heat-treatment, and a large amount of electric charges escape after heat-treatment is performed. When the channel region includes impurities, an amount of electric charges trapped prior to heat-treatment is smaller than the case where the channel region does not include any impurity, and an amount of electric charges escaping after heat-treatment is performed is smaller than the case where the channel region does not include any impurity. Thus, like in FIG. 11A, it is expected that as an amount of impurities included in the channel region is increased, the HTS characteristics are improved. However, if a doping concentration of the channel region is excessively increased, the threshold voltage (Vₜₕ) is also increased and, thus, it is difficult to perform an erasing operation of a non-volatile memory device. Thus, it has been found that it is desirable to control the channel region so as to have a desired impurity concentration.

According to various embodiments described herein, since impurities may be doped on the channel region, and an impurity concentration may be controlled, the reliability of a non-volatile memory device may be improved.

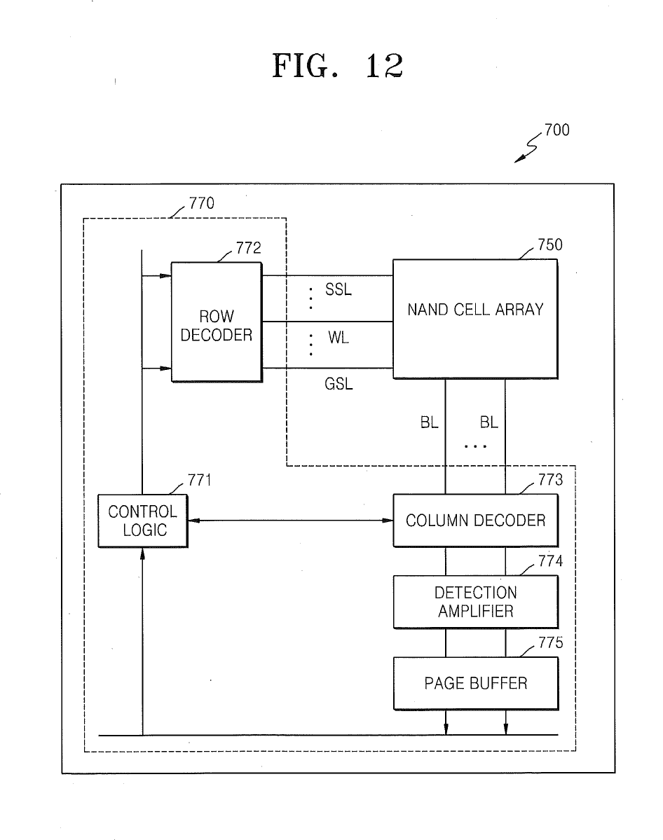

FIG. 12 is a schematic block diagram of a non-volatile memory device 700 according to various embodiments described herein.

Referring to FIG. 12, in the non-volatile memory device 700, a NAND cell array 750 may be coupled to a core circuit unit 770. For example, the NAND cell array 750 may include any one of the non-volatile memory devices 1000a, 1000b, 1000c, 2000a, 2000b and 2000c of FIGS. 3 and 5 through 11. The core circuit unit 770 may include a control logic 771, a row decoder 772, a column decoder 773, a detection amplifier 774 and a page buffer 775.

The control logic 771 may communicate with the row decoder 772, the column decoder 773 and the page buffer 775. The row decoder 772 may communicate with the NAND cell array 750 through a plurality of string selection lines SSL, a plurality of word lines WL and a plurality of ground selection lines GSL. The column decoder 773 may communicate with the NAND cell array 750 through a plurality of bit lines BL. The detection amplifier 774 may be connected to the column decoder 773 when a signal is output from the NAND cell array 750. The detection amplifier 774 may not be connected to the column decoder 773 when a signal is transmitted to the NAND cell array 750.

For example, the control logic 771 may transmit a row address signal to the row decoder 772. In addition, the row decoder 772 may decode the row address signal, and may transmit the row address signal to the NAND cell array 750 through the string selection lines SSL, the word lines WL and the ground selection lines GSL. The control logic 771 transmits a column address signal to the column decoder 773 or the page buffer 775. The column decoder 773 may decode the column address signal, and may transmit the column address signal to the NAND cell array 750 through the bit lines BL. Signals of the NAND cell array 750 may be transmitted to the detection amplifier 774 through the column decoder 773, may be amplified by the detection amplifier 774, and then may be transmitted to the control logic 771 through the page buffer 775.

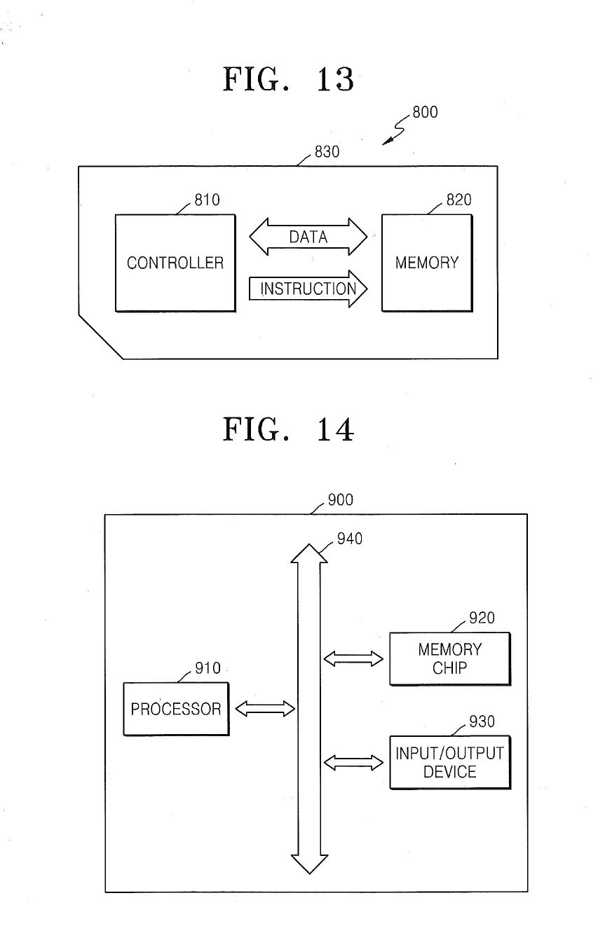

FIG. 13 is a schematic diagram of a memory card 800 according to various embodiments described herein.

Referring to FIG. 13, the memory card 800 may include a controller 810 and a memory 820, which are included in a housing 830. The controller 810 and the memory 820 may exchange electrical signals. For example, according to an instruction of the controller 810, the memory 820 and the controller 810 may transfer data. Thus, the memory card 800 may store data in the memory 820 or may output data from the memory 820.

For example, the memory 820 may include any one of the non-volatile memory devices 1000a, 1000b, 1000c, 2000a, 2000b and 2000c of FIGS. 3, 5 through 7, 9 and 10. The memory card 800 may be used as a data storage medium of various portable devices. For example, the memory card 800 may include a multi media card (MMC) or a secure digital card (SD).

FIG. 14 is a schematic diagram of an electronic system 900 according to various embodiments described herein.

Referring to FIG. 14, the electronic system 900 may include a processor 910, an input/output device 930 and a memory chip 920, which data-communicate with each other via a bus 940. The processor 910 may execute programs, and may control the electronic system 900. The input/output device 930 may be used to input or output data of the electronic system 900. The electronic system 900 may be connected to an external device, for example, a personal computer or a network by using the input/output device 930, and may exchange data with the external device. The memory chip 920 may storage codes and data for an operation of the processor 910. For example, the memory chip 920 may include any one of the non-volatile memory devices 1000a, 1000b, 1000c, 2000a, 2000b and 2000c of FIGS. 3, 5 through 7, 9 and 10.

The electronic system 900 may constitute various electronic controlling devices requiring the memory chip 920, and may be used in a mobile phone, an MP3 player, a navigation device, a solid state disk (SSD) and/or a household appliance.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A vertical structure non-volatile memory device comprising:
a channel region that vertically extends on a substrate;
a memory cell string that vertically extends on the substrate along a first wall of the channel region, and comprises at least one selection transistor and at least one memory cell; and
an impurity providing layer disposed on a second wall of the channel region and comprising impurities.

2. The vertical structure non-volatile memory device of claim 1, wherein the impurity providing layer comprises an insulating material doped with impurities and/or a semiconductor material doped with impurities.

3. The vertical structure non-volatile memory device of claim 2, wherein the impurity providing layer comprises a semiconductor material doped with impurities, and wherein the channel region is electrically connected to the substrate through the impurity providing layer.

4. The vertical structure non-volatile memory device of claim 1, wherein the channel region has a first impurity concentration, and
wherein the impurity providing layer has a second impurity concentration that is higher than the first impurity concentration.

5. The vertical structure non-volatile memory device of claim 4, wherein the first impurity concentration is from 10¹⁸/cm³ to 10¹⁹/cm³, and
wherein the second impurity concentration is from 10¹⁹/cm³ to 10²¹/cm³.

6. The vertical structure non-volatile memory device of claim 1, wherein the channel region is electrically connected to the substrate.

7. The vertical structure non-volatile memory device of claim 1, wherein the impurities are group III or V elements that are diffused to the channel region from the impurity providing layer by heat-treatment.

8. The vertical structure non-volatile memory device of claim 1, further comprising a diffusion controlling layer disposed between the channel region and the impurity providing layer.

9. The vertical structure non-volatile memory device of claim 8, wherein the diffusion controlling layer is configured to reduce, but not block, diffusion of impurities from the impurity providing layer to the channel region.

10. The vertical structure non-volatile memory device of claim 8, wherein the channel region is electrically connected to the substrate through the diffusion controlling layer.

11. The vertical structure non-volatile memory device of claim 1, wherein the impurity providing layer comprises any one or more of phosphosilicate glass (PSG), borosilicate glass (BSG), or doped polysilicon.

12. The vertical structure non-volatile memory device of claim 1, wherein the at least one memory cell and the at least one selection transistor comprises a gate dielectric layer and a gate electrode on the first wall of the channel region.

13. A semiconductor device comprising:
a transistor comprising a channel region; and
an impurity providing layer disposed at one side of the channel region, and comprising impurities to be provided to the channel region.

14. The semiconductor device of claim 13, wherein the impurity providing layer comprises an insulating material doped with impurities and/or a semiconductor material doped with impurities.

15. The semiconductor device of claim 14, wherein the channel region has a first impurity concentration, and
wherein the impurity providing layer has a second impurity concentration that is higher than the first impurity concentration.

16. A vertical transistor structure comprising:
a substrate including a horizontal surface;
a column on the substrate that extends vertically away from the horizontal surface and includes a wall that extends vertically away from the horizontal surface;
a channel region on the wall of the column and that extends vertically away from the horizontal surface;
a gate dielectric on the channel region opposite the column and that extends vertically away from the horizontal surface; and
a plurality of gate electrodes that are stacked upon one another on the horizontal surface and that extend adjacent the gate dielectric opposite the channel region,
wherein the column is more heavily doped with impurities than the channel region.

17. The vertical transistor structure of claim 16 wherein the gate dielectric comprises a tunneling insulator, a charge storage layer and a blocking insulating layer, all of which extend vertically away from the horizontal surface.

18. The vertical transistor structure of claim 16 wherein the column comprises a hollow or solid column that is doped with the impurities.

19. The vertical transistor structure of claim 16 wherein the column comprises semiconductor material and/or insulating material that is doped with the impurities.

20. The vertical transistor structure of claim 16 further comprising a diffusion controlling layer between the channel region and the column that extends vertically away from the horizontal surface and that is configured to reduce, but not block, diffusion of the impurities from the column to the channel region.
